(19) United States
(12) Patent Application Publication
(10) Pub. No.: US 2025/0393375 A1
(43) Pub. Date: Dec. 25, 2025

(54) DISPLAY DEVICE

(71) Applicant: Innolux Corporation, Miaoli County (TW)

(72) Inventors: Chih-Lung Lin, Miaoli County (TW); Kuan-Hung Kuo, Miaoli County (TW); Yi-An Chen, Miaoli County (TW); Wei-Chih Chen, Miaoli County (TW); Yu-Syuan Chen, Miaoli County (TW); Ying-Tzu Cheng, Miaoli County (TW)

(73) Assignee: Innolux Corporation, Miaoli County (TW)

(21) Appl. No.: 19/218,603

(22) Filed: May 26, 2025

Related U.S. Application Data
(60) Provisional application No. 63/662,422, filed on Jun. 21, 2024.

(30) Foreign Application Priority Data
Nov. 18, 2024 (CN) 202411647883.5

(51) Int. Cl. H10H 29/85; H10H 29/37; H10H 29/80; H10H 29/855; H10K 59/122; H10K 59/126; H10K 59/38; H10K 59/80; H10K 102/00

(52) U.S. Cl. CPC H10H 29/8517; H10H 29/37; H10H 29/8552; H10H 29/8581; H10H 29/882; H10K 59/122; H10K 59/126; H10K 59/38; H10K 59/8792; H10K 59/8794; H10K 2102/331

(57) ABSTRACT

A display device includes a first substrate, a plurality of light-emitting units, and a plurality of color filter units. The light-emitting units are disposed on the first substrate and include a first light-emitting unit, a second light-emitting unit, and a third light-emitting unit. The first light-emitting unit, the second light-emitting unit, and the third light-emitting unit emit light of different colors respectively. The color filter units are disposed on the light-emitting units and include a first color filter unit, a second color filter unit, and a third color filter unit. The first color filter unit, the second color filter unit, and the third color filter unit overlap the first light-emitting unit, the second light-emitting unit, and the third light-emitting unit respectively. The first color filter unit, the second color filter unit, and the third color filter unit include a scattering particle.

### CROSS-REFERENCE TO RELATED APPLICATION

This application claims the priority benefit of U.S. provisional application Ser. No. 63/662,422, filed on Jun. 21, 2024, and China application serial no. 202411647883.5, filed on Nov. 18, 2024. The entirety of each of the above-mentioned patent applications is hereby incorporated by reference herein and made a part of this specification.

### BACKGROUND

### Technical Field

The disclosure relates to a display device, particularly to a display device that may improve the problem of uneven brightness when viewing from different viewing angles.

### Description of Related Art

The electronic device or the tiled electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The disclosure provides a display device that may improve the problem of uneven brightness when viewing from different viewing angles.

According to an embodiment of the disclosure, the display device includes a first substrate, a plurality of light-emitting units, and a plurality of color filter units. The plurality of light-emitting units are disposed on the first substrate. The plurality of light-emitting units include a first light-emitting unit, a second light-emitting unit, and a third light-emitting unit. The first light-emitting unit, the second light-emitting unit, and the third light-emitting unit emit light of different colors respectively. The plurality of color filter units are disposed on the plurality of light-emitting units. The plurality of color filter units include a first color filter unit, a second color filter unit, and a third color filter unit. The first color filter unit, the second color filter unit, and the third color filter unit overlap with the first light-emitting unit, the second light-emitting unit, and the third light-emitting unit respectively. The first color filter unit, the second color filter unit, and the third color filter unit include a scattering particle.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a cross-sectional schematic view of a display device according to the first embodiment of the disclosure.

FIG. 2 is a cross-sectional schematic view of a display device according to the second embodiment of the disclosure.

FIG. 3 is a cross-sectional schematic view of a display device according to the third embodiment of the disclosure.

FIG. 4 is a cross-sectional schematic view of a display device according to the fourth embodiment of the disclosure.

FIG. 5 is a cross-sectional schematic view of a display device according to the fifth embodiment of the disclosure.

FIG. 6 is a cross-sectional schematic view of a display device according to the sixth embodiment of the disclosure.

FIG. 7 is a cross-sectional schematic view of a display device according to the seventh embodiment of the disclosure.

FIG. 8 is a cross-sectional schematic view of a display device according to the eighth embodiment of the disclosure.

FIG. 9 is a cross-sectional schematic view of a display device according to the ninth embodiment of the disclosure.

FIG. 10 is a cross-sectional schematic view of a display device according to the tenth embodiment of the disclosure.

FIG. 11 is a cross-sectional schematic view of a display device according to the eleventh embodiment of the disclosure.

FIG. 12 is a cross-sectional schematic view of a display device according to the twelfth embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a single constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect connection means.

In some embodiments of the disclosure, an optical microscope (OM), a scanning electron microscope (SEM), a thin film thickness profilometer (α-step), an ellipsometer, or other suitable manners may be used to measure an area, a width, a thickness, or a height of each element or a distance or a spacing between elements. In detail, according to some embodiments, the scanning electron microscope may be used to obtain a cross-sectional structural image including the element to be measured and measure the area, the width, the thickness, or the height of each element or the distance or the spacing between the elements.

In the disclosure, the electronic device may include a display device, light emitting device, backlight device, virtual reality device, augmented reality (AR) device, antenna device, sensing device, tiled device, or any combination thereof, but not limited thereto. The display device may be a non-self-luminous display or a self-luminous display according to requirements, and may be a color display or a monochrome display according to requirements. The antenna device may be a liquid crystal type antenna device or a non-liquid crystal type antenna device. The sensing device may be a device for sensing capacitance, light, thermal energy, or ultrasound. The tiled device may be a display tiled device or an antenna tiled device, but not limited thereto. The electronic units in the electronic device may include passive components and active components, such as capacitors, resistors, inductors, diodes, transistors, etc. The diode may include a light emitting diode (LED) or a photodiode. The light emitting diode may include, for example, an organic light emitting diode (OLED), a mini LED, a micro LED, or a quantum dot LED, but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have peripheral systems such as driving systems, control systems, light source systems, etc. to support display devices, antenna devices, wearable devices (including augmented reality or virtual reality devices, for example), vehicle-mounted devices (including car windshields, for example), or tiled devices. It should be noted that the electronic device may be any permutation and combination of the above, but not limited thereto. The following will use the display device to explain the content of the disclosure, but the disclosure is not limited thereto.

It should be noted that in the following embodiments, without departing from the spirit of the disclosure, features in several different embodiments may be replaced, reorganized, and mixed to complete other embodiments. As long as the features of the embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

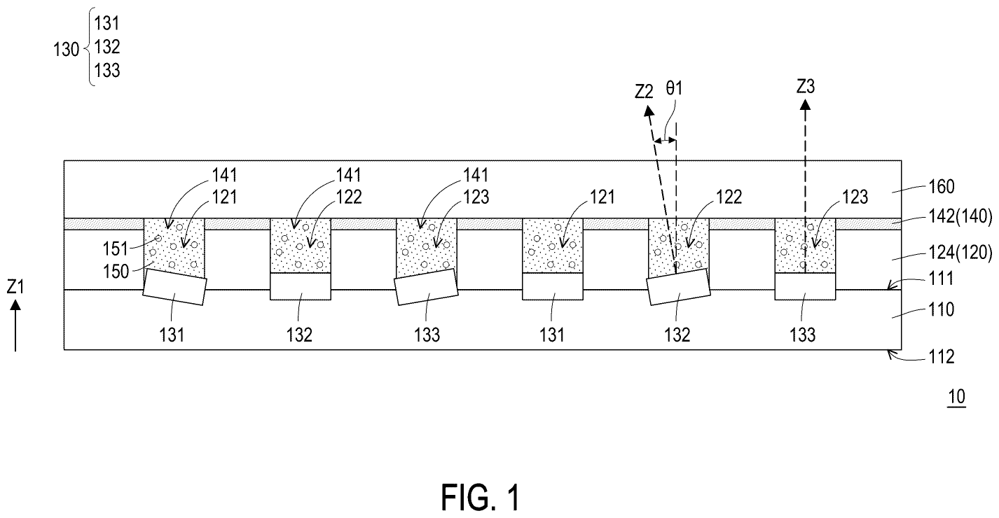

FIG. 1 is a cross-sectional view of a display device according to a first embodiment of the disclosure. Referring to FIG. 1, the display device 10 includes a first substrate 110, a pixel definition layer 120, a plurality of light-emitting units 130, a black matrix layer 140, a scattering material layer 150, and a cover glass 160.

Specifically, the first substrate 110 has a surface 111 and a surface 112 opposite to each other. The first substrate 110 may be, for example, a circuit board including a circuit layer. For example, the first substrate 110 may be an active-drive substrate or a passive-drive substrate for driving the light-emitting units 130. The active-drive substrate may include driving circuits (not shown) such as transistors, scan lines, data lines, etc., but not limited thereto. The passive-drive substrate may include micro integrated circuits, but not limited thereto. In the embodiment, the first substrate 110 may include rigid materials, flexible materials, or a combination thereof. For example, the material of the base of the first substrate 110 may include glass, quartz, sapphire, ceramic, polycarbonate (PC), polyimide (PI), polyethylene terephthalate (PET), or a combination thereof, but not limited thereto.

The pixel definition layer 120 is disposed on the surface 111 of the first substrate 110. The pixel definition layer 120 includes a first opening 121, a second opening 122, a third opening 123, and a partition 124. The first opening 121, the second opening 122, and the third opening 123 may expose a portion of the first substrate 110. In the embodiment, the material of the partition 124 may include organic photoresist, and the color of the partition 124 may be transparent, black, gray, or white, but not limited thereto.

The plurality of light-emitting units 130 are disposed on the surface 111 of the first substrate 110. The plurality of light-emitting units 130 include a first light-emitting unit 131, a second light-emitting unit 132, and a third light-emitting unit 133. The first light-emitting unit 131 is disposed in the first opening 121, the second light-emitting unit 132 is disposed in the second opening 122, and the third light-emitting unit 133 is disposed in the third opening 123. In the embodiment, the first light-emitting unit 131, the second light-emitting unit 132, and the third light-emitting unit 133 may emit light of different colors. For example, the first light-emitting unit 131 may emit red light, the second light-emitting unit 132 may emit green light, and the third light-emitting unit 133 may emit blue light, but not limited thereto. In the embodiment, the light-emitting units 130 may include organic light-emitting diodes, inorganic light-emitting diodes, or a combination thereof, but not limited thereto. The inorganic light-emitting diodes may be, for example, mini light-emitting diodes or micro light-emitting diodes, etc.

The black matrix layer 140 is disposed on the pixel definition layer 120. The black matrix layer 140 includes a plurality of fourth openings 141 and a black matrix material layer 142. In a normal direction Z1 of the first substrate 110 or in a normal direction Z1 of the display device 10, the plurality of fourth openings 141 may respectively correspond to and overlap with the first opening 121, the second opening 122 and the third opening 123, the plurality of fourth openings 141 may respectively correspond to and overlap with the first light-emitting unit 131, the second light-emitting unit 132 and the third light-emitting unit 133, and the black matrix material layer 142 may correspond to and overlap with the partition 124 of the pixel definition layer 120. In the embodiment, the material of the black matrix material layer 142 may include light-absorbing material, for example, black photoresist, but not limited thereto.

The scattering material layer 150 is disposed on the plurality of light-emitting units 130 in the first opening 121, the second opening 122, and the third opening 123 of the pixel definition layer 120. In the normal direction Z1 of the first substrate 110 or in the normal direction Z1 of the display device 10, the scattering material layer 150 may correspond to and overlap with the light-emitting units 130. The scattering material layer 150 may include a scattering particle 151 to scatter the light emitted by the plurality of light-emitting units 130. In the embodiment, the material of the scattering particle 151 may include titanium oxide (TiO₂), zinc oxide (ZnO), silicon oxide (SiO₂), barium oxide (BaO), barium sulfate (BaSO₄), zirconium oxide (ZrO₂), or a combination thereof, but not limited thereto. In some embodiments, the scattering material layer 150 may further include a heat-dissipating particle (not shown); wherein the material of the heat-dissipating particle may include boron nitride (BN), aluminum nitride (AlN), silicon carbide (SiC), silicon nitride (Si₃N₄), beryllium oxide (BeO), aluminum oxide (Al₂O₃), or a combination thereof; and a thermal conductivity coefficient of the heat-dissipating particle may be, for example, greater than 50 W·m⁻¹·K⁻¹, or between 50 W·m⁻¹·K⁻¹ and 1000 W·m⁻¹·K⁻¹ (50 W·m⁻¹·K⁻¹≤thermal conductivity coefficient≤1000 W·m⁻¹·K⁻¹).

The cover glass 160 is disposed on the black matrix layer 140. In the embodiment, the material of the cover glass 160 may include glass or other suitable transparent substrate materials, but not limited thereto.

In the embodiment, the plurality of light-emitting units 130 may be placed on the surface 111 of the first substrate 110 through a transfer method and a bonding method, for example. Due to process errors during the transfer process or the bonding process, a normal direction Z2 of the light-emitting surface of a portion of the light-emitting units 130 is not substantially parallel to the normal direction Z1 of the first substrate 110, while a normal direction Z3 of the light-emitting surface of another portion of the light-emitting units 130 may be substantially parallel to the normal direction Z1 of the first substrate 110. In other words, the normal direction Z2 of the light-emitting surface of the portion of the light-emitting units 130 is different from the normal direction Z3 of the light-emitting surface of the another portion of the light-emitting units 130. The normal direction Z2 of the light-emitting surface of the portion of the light-emitting units 130 is tilted relative to the normal direction Z1 of the first substrate 110, and there is a tilt angle θ1 between the normal direction Z2 of the light-emitting surface of the portion of the light-emitting units 130 and the normal direction Z1 of the first substrate 110.

In a conventional display device, when the light-emitting surface of some light-emitting units is tilted, the light-emitting direction (or photon movement direction) of some light-emitting units may be different from the light-emitting direction (or photon movement direction) of other light-emitting units, resulting in the problem of uneven brightness when viewing the display device from different viewing angles (for example, obvious bright or dark areas at oblique viewing angles). However, in the display device 10 of the embodiment, by disposing the scattering material layer 150 on the light-emitting units 130, the scattering particle 151 in the scattering material layer 150 may be used to adjust the light-emitting direction (or light-emitting angle) of the tilted light-emitting units 130, thereby improving the problem of uneven brightness when viewing from different viewing angles or maintaining similar brightness for the user when viewing from different angles.

Other embodiments will be listed below as illustrations. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

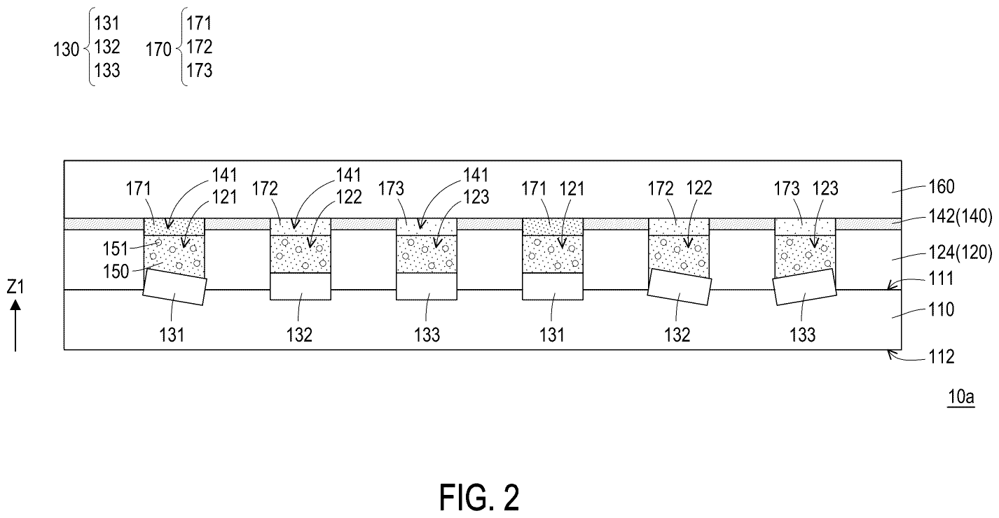

FIG. 2 is a cross-sectional schematic view of a display device according to a second embodiment of the disclosure. Please refer to FIG. 2 and FIG. 1 simultaneously. A display device 10a of the embodiment is similar to the display device 10 in FIG. 1. The difference between the two is that the display device 10a of the embodiment further includes a plurality of color filter units 170.

Specifically, referring to FIG. 2, the plurality of color filter units 170 are disposed on the plurality of light-emitting units 130 and the scattering material layer 150. The plurality of color filter units 170 are disposed in the fourth opening 141 of the black matrix layer 140, and the scattering material layer 150 is disposed between the plurality of color filter units 170 and the plurality of light-emitting units 130.

The plurality of color filter units 170 include a first color filter unit 171, a second color filter unit 172, and a third color filter unit 173. For example, the first color filter unit 171 may be a red filter unit, the second color filter unit 172 may be a green filter unit, and the third color filter unit 173 may be a blue filter unit, so that color filter units of different colors may be matched with light-emitting units of corresponding colors, but not limited thereto.

In the normal direction Z1 of the first substrate 110 or in the normal direction Z1 of the display device 10a, the first color filter unit 171, the second color filter unit 172, and the third color filter unit 173 respectively overlap with the first light-emitting unit 131, the second light-emitting unit 132, and the third light-emitting unit 133.

In the display device 10a of the embodiment, by disposing the scattering material layer 150 between the color filter units 170 and the light-emitting units 130, the scattering particle 151 in the scattering material layer 150 may be used to adjust the light-emitting direction (or light-emitting angle) of the tilted light-emitting units 130, thereby improving the problem of uneven brightness when viewing from different viewing angles or maintaining similar brightness for the user when viewing from different angles.

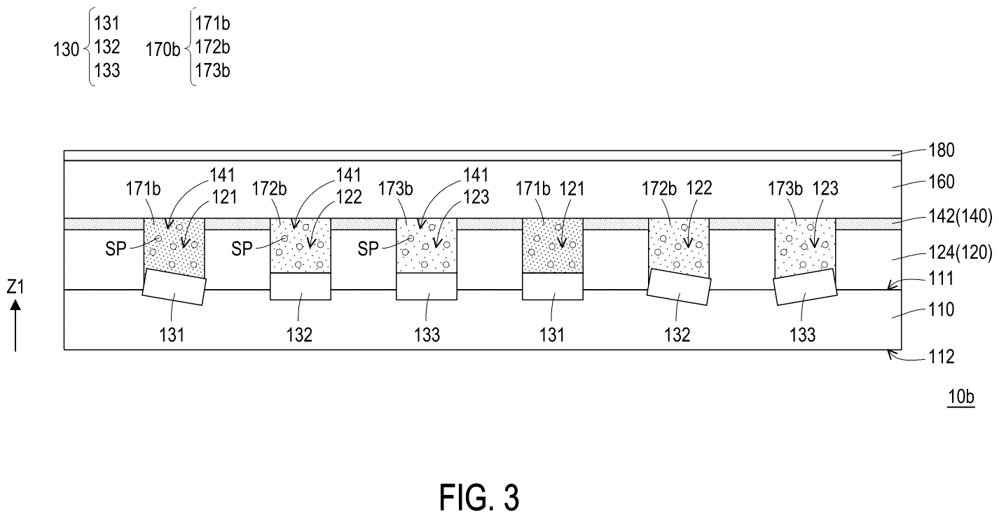

FIG. 3 is a cross-sectional schematic view of a display device according to a third embodiment of the disclosure. Please refer to FIG. 3 and FIG. 1 simultaneously. A display device 10b of the embodiment is similar to the display device 10 in FIG. 1. The difference between the two is that the display device 10b of the embodiment further includes a plurality of color filter units 170b and a functional layer 180, and the plurality of color filter units 170b may be used to replace the scattering material layer 150 in FIG. 1.

Specifically, referring to FIG. 3, the plurality of color filter units 170b are disposed on the plurality of light-emitting units 130. The plurality of color filter units 170b are disposed on the plurality of light-emitting units 130 in the first opening 121, the second opening 122, and the third opening 123 of the pixel definition layer 120. In the embodiment, the plurality of color filter units 170b may contact the light-emitting units 130, but not limited thereto.

The plurality of color filter units 170b include a first color filter unit 171b, a second color filter unit 172b, and a third color filter unit 173b. For example, the first color filter unit 171b may be a red filter unit, the second color filter unit 172b may be a green filter unit, and the third color filter unit 173b may be a blue filter unit, so that color filter units of different colors may be matched with light-emitting units of corresponding colors, but not limited thereto.

The first color filter unit 171b is disposed in the first opening 121 and the fourth opening 141, the second color filter unit 172b is disposed in the second opening 122 and the fourth opening 141, and the third color filter unit 173b is disposed in the third opening 123 and the fourth opening 141. In the normal direction Z1 of the first substrate 110 or in the normal direction Z1 of the display device 10b, the first color filter unit 171b, the second color filter unit 172b, and the third color filter unit 173b respectively overlap with the first light-emitting unit 131, the second light-emitting unit 132, and the third light-emitting unit 133.

The first color filter unit 171b, the second color filter unit 172b, and the third color filter unit 173b include scattering particle SP to scatter the light emitted by the plurality of light-emitting units 130. In the embodiment, the material of the scattering particle SP may include titanium oxide (TiO₂), zinc oxide (ZnO), silicon oxide (SiO₂), barium oxide (BaO), barium sulfate (BaSO₄), zirconium oxide (ZrO₂), or a combination thereof, but not limited thereto. In some embodiments, the first color filter unit 171b, the second color filter unit 172b, and the third color filter unit 173b may further include heat-dissipating particle (not shown); wherein the material of the heat-dissipating particle may include boron nitride (BN), aluminum nitride (AlN), silicon carbide (SiC), silicon nitride (Si₃N₄), beryllium oxide (BeO), aluminum oxide (Al₂O₃), or a combination thereof; and the thermal conductivity coefficient of the heat-dissipating particle may, for example, be greater than 50 W·m⁻¹·K⁻¹, or between 50 W·m⁻¹·K⁻¹ and 1000 W·m⁻¹·K⁻¹ (50 W·m⁻¹·K⁻¹≤thermal conductivity coefficient≤1000 W·m⁻¹·K⁻¹).

The functional layer 180 is disposed on the cover glass 160 to protect the display device 10b. The functional layer 180 may include an anti-reflective layer (AR), an anti-smudge layer (AS), or a combination of both. In the embodiment, the anti-reflective layer may include a distributed Bragg reflector (DBR), and the material of the anti-smudge layer may include fluorides (for example, fluoropolymers), but not limited thereto. In the embodiment, the functional layer 180 includes an anti-reflective layer and an anti-smudge layer, and the anti-smudge layer is disposed on the anti-reflective layer.

In the display device 10b of the embodiment, by disposing the color filter units 170b containing scattering particle SP on the light-emitting units 130, the scattering particle SP in the color filter units 170b may be used to adjust the light-emitting direction (or light-emitting angle) of the tilted light-emitting units 130, thereby improving the problem of uneven brightness when viewing from different viewing angles or maintaining similar brightness for the user when viewing from different angles.

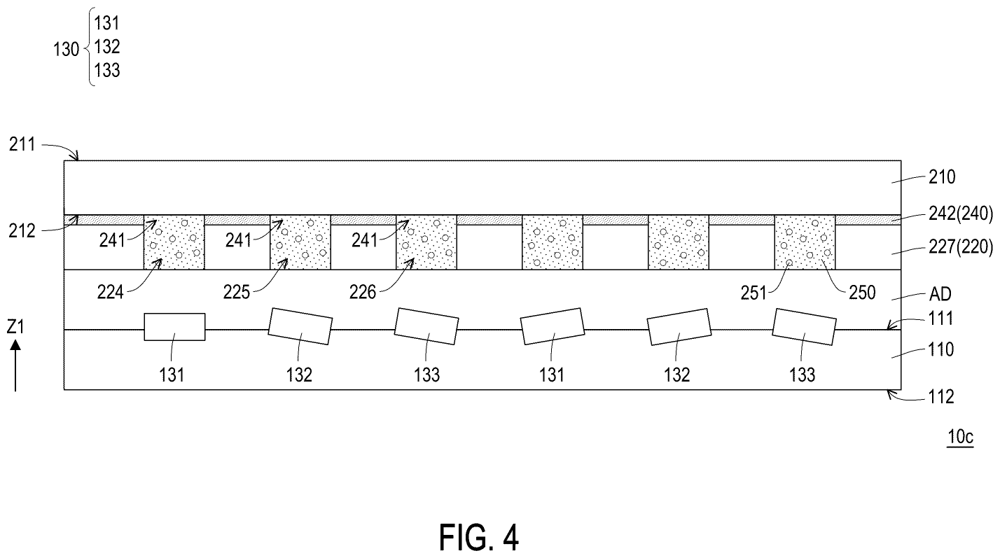

FIG. 4 is a cross-sectional schematic view of a display device according to the fourth embodiment of the disclosure. Please refer to FIG. 4 and FIG. 1 simultaneously. A display device 10c of the embodiment is similar to the display device 10 in FIG. 1. The difference between the two is that the display device 10c of the embodiment further includes a second substrate 210, an adhesive layer AD, and a bank layer 220.

Specifically, referring to FIG. 4, the display device 10c of the embodiment does not disposed the pixel definition layer as shown in FIG. 1, but not limited thereto. In some embodiments, a pixel definition layer may also be optionally disposed according to requirements or design needs, and the pixel definition layer may have openings for accommodating the light-emitting units.

The second substrate 210 is disposed opposite to the first substrate 110. The second substrate 210 has a surface 211 and a surface 212 opposite to each other, and the surface 212 faces the surface 111 of the first substrate 110. In the embodiment, the material of the second substrate 210 may include glass or other suitable transparent substrate materials, but not limited thereto.

The bank layer 220 is disposed on the surface 212 of the second substrate 210. The bank layer 220 includes a fifth opening 224, a sixth opening 225, a seventh opening 226, and a partition 227. The fifth opening 224, sixth opening 225, and seventh opening 226 may expose parts of the second substrate 210. In the embodiment, the material of the partition 227 may include organic photoresist, and the color of the partition 227 may be black or white, but not limited thereto. In some embodiments, the partition 227 may include scattering particle (not shown) to increase the reflectivity of the partition 227.

The black matrix layer 240 is disposed between the bank layer 220 and the second substrate 210. The black matrix layer 240 includes a plurality of eighth openings 241 and a black matrix material layer 242. In the normal direction Z1 of the first substrate 110 or in the normal direction Z1 of the display device 10c, the plurality of eighth openings 241 may respectively correspond to and overlap with the fifth opening 224, the sixth opening 225, and the seventh opening 226, the plurality of eighth openings 241 may respectively correspond to and overlap with the first light-emitting unit 131, the second light-emitting unit 132, and the third light-emitting unit 133, and the black matrix material layer 242 may correspond to and overlap with the partition 227 of the bank layer 220.

The scattering material layer 250 is disposed on the plurality of light-emitting units 130, and the scattering material layer 250 is disposed in the fifth opening 224, sixth opening 225, and seventh opening 226 of the bank layer 220. In the normal direction Z1 of the first substrate 110 or in the normal direction Z1 of the display device 10c, the scattering material layer 250 may correspond to and overlap with the light-emitting units 130. The scattering material layer 250 may include scattering particle 251 to scatter the light emitted by the plurality of light-emitting units 130.

The adhesive layer AD is disposed between the plurality of light-emitting units 130 and the scattering material layer 250. The adhesive layer AD may be used for bonding the first substrate 110 and the second substrate 210. In the embodiment, the material of the adhesive layer AD may include optical clear adhesive (OCA), optical clear resin (OCR), other suitable adhesive materials, or a combination thereof, but not limited thereto.

In the display device 10c of the embodiment, by disposing the scattering material layer 250 on the light-emitting units 130, the scattering particle 251 in the scattering material layer 250 may be used to adjust the light-emitting direction (or light-emitting angle) of the tilted light-emitting units 130, thereby improving the problem of uneven brightness when viewing from different viewing angles or maintaining similar brightness for the user when viewing from different angles.

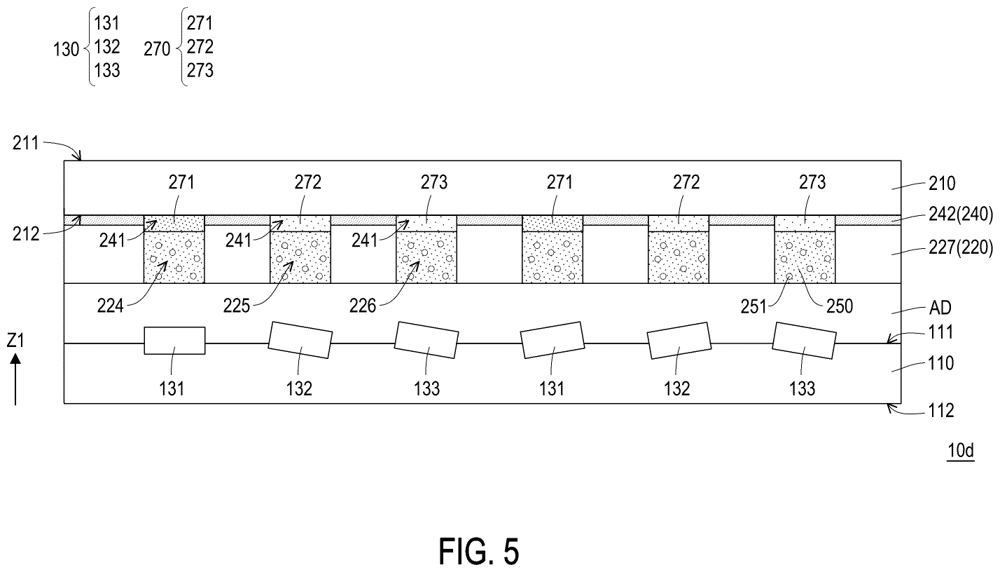

FIG. 5 is a cross-sectional schematic diagram of a display device according to the fifth embodiment of the disclosure. Please refer to FIG. 5 and FIG. 4 simultaneously. A display device 10d of the embodiment is similar to the display device 10c in FIG. 4. The difference between the two is that the display device 10d of the embodiment further includes a plurality of color filter units 270.

Specifically, referring to FIG. 5, the plurality of color filter units 270 are disposed on

the plurality of light-emitting units 130 and the scattering material layer 250. The plurality of color filter units 270 are disposed in the eighth openings 241 of the black matrix layer 240, and the scattering material layer 250 is disposed between the plurality of color filter units 270 and the plurality of light-emitting units 130.

The plurality of color filter units 270 include a first color filter unit 271, a second color filter unit 272, and a third color filter unit 273. For example, the first color filter unit 271 may be a red filter unit, the second color filter unit 272 may be a green filter unit, and the third color filter unit 273 may be a blue filter unit, so that color filter units of different colors may be matched with light-emitting units of corresponding colors, but not limited thereto.

In the normal direction Z1 of the first substrate 110 or in the normal direction Z1 of the display device 10d, the first color filter unit 271, the second color filter unit 272, and the third color filter unit 273 respectively overlap with the first light-emitting unit 131, the second light-emitting unit 132, and the third light-emitting unit 133.

In the display device 10d of the embodiment, by disposing the scattering material layer 250 between the color filter units 270 and the light-emitting units 130, the scattering particle 251 in the scattering material layer 250 may be used to adjust the light-emitting direction (or light-emitting angle) of the tilted light-emitting units 130, thereby improving the problem of uneven brightness when viewing from different viewing angles or maintaining similar brightness for the user when viewing from different angles.

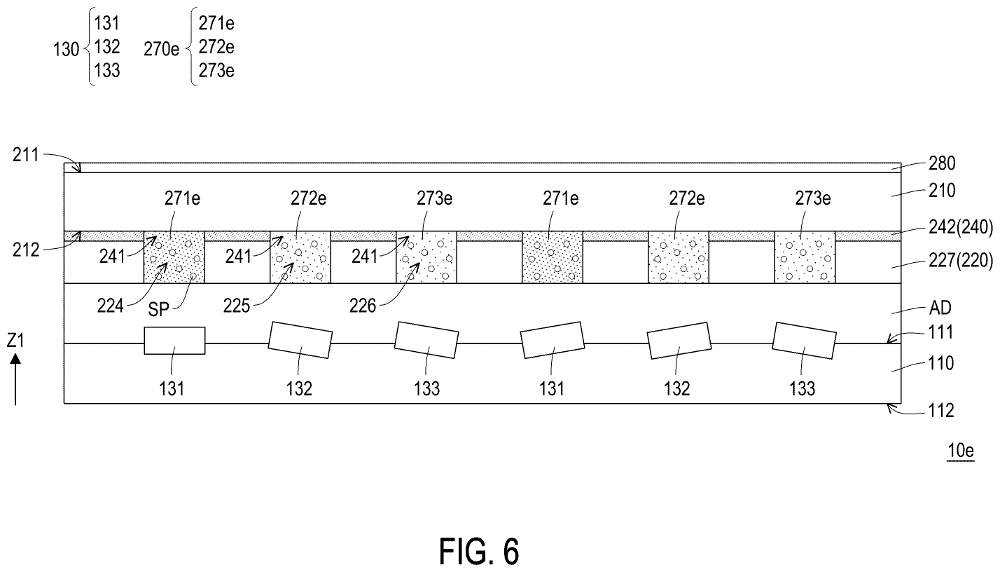

FIG. 6 is a cross-sectional schematic diagram of a display device according to the sixth embodiment of the disclosure. Please refer to FIG. 6 and FIG. 1 simultaneously. A display device 10e of the embodiment is similar to the display device 10c in FIG. 4. The difference between the two is that the display device 10e of the embodiment further includes a plurality of color filter units 270e and a functional layer 280, and the plurality of color filter units 270e may be used to replace the scattering material layer 250 in FIG. 4.

Specifically, referring to FIG. 6, the plurality of color filter units 270e are disposed on the plurality of light-emitting units 130. The plurality of color filter units 270e are disposed in the fifth opening 224, sixth opening 225, and seventh opening 226 of the bank layer 220, and the adhesive layer AD is disposed between the plurality of light-emitting units 130 and the plurality of color filter units 270e. In the embodiment, there is a gap between the color filter units 270e and the light-emitting units 130, but not limited thereto.

The plurality of color filter units 270e include a first color filter unit 271e, a second color filter unit 272e, and a third color filter unit 273e. For example, the first color filter unit 271e may be a red filter unit, the second color filter unit 272e may be a green filter unit, and the third color filter unit 273e may be a blue filter unit, so that color filter units of different colors may be matched with light-emitting units of corresponding colors, but not limited thereto.

The first color filter unit 271e is disposed in the fifth opening 224 and the eighth opening 241, the second color filter unit 272e is disposed in the sixth opening 225 and the eighth opening 241, and the third color filter unit 273e is disposed in the seventh opening 226 and the eighth opening 241. In the normal direction Z1 of the first substrate 110 or in the normal direction Z1 of the display device 10e, the first color filter unit 271e, the second color filter unit 272e, and the third color filter unit 273e respectively overlap with the first light-emitting unit 131, the second light-emitting unit 132, and the third light-emitting unit 133.

The first color filter unit 271e, the second color filter unit 272e, and the third color filter unit 273e include scattering particle SP to scatter the light emitted by the plurality of light-emitting units 130. In the embodiment, the material of the scattering particle SP may include titanium oxide (TiO₂), zinc oxide (ZnO), silicon oxide (SiO₂), barium oxide (BaO), barium sulfate (BaSO₄), zirconium oxide (ZrO₂), or a combination thereof, but not limited thereto. In some embodiments, the first color filter unit 271e, the second color filter unit 272e, and the third color filter unit 273e may further include heat-dissipating particle (not shown); wherein the material of the heat-dissipating particle may include boron nitride (BN), aluminum nitride (AlN), silicon carbide (SiC), silicon nitride (Si₃N₄), beryllium oxide (BeO), aluminum oxide (Al₂O₃), or a combination thereof; and the thermal conductivity coefficient of the heat-dissipating particle may be, for example, greater than 50 W·m⁻¹·K⁻¹, or between 50 W·m⁻¹·K⁻¹ and 1000 W·m⁻¹·K⁻¹ (50 W·m⁻¹·K⁻¹≤thermal conductivity coefficient≤1000 W·m⁻¹·K⁻¹).

The functional layer 280 is disposed on the surface 211 of the second substrate 210 to protect the display device 10e. The functional layer 280 and the black matrix layer 240 are respectively disposed on two opposite sides of the second substrate 210. The functional layer 280 may include an anti-reflective layer, an anti-smudge layer, or a combination of both. In the embodiment, the anti-reflective layer may include a distributed Bragg reflector, and the material of the anti-smudge layer may include fluorides (for example, fluoropolymers), but not limited thereto. In the embodiment, the functional layer 280 includes an anti-reflective layer and an anti-smudge layer, and the anti-smudge layer is disposed on the anti-reflective layer. In the display device 10e of the embodiment, by disposing the color filter units 270e

containing scattering particle SP on the light-emitting units 130, the scattering particle SP in the color filter units 270e may be used to adjust the light-emitting direction (or light-emitting angle) of the tilted light-emitting units 130, thereby improving the problem of uneven brightness when viewing from different viewing angles or maintaining similar brightness for the user when viewing from different angles.

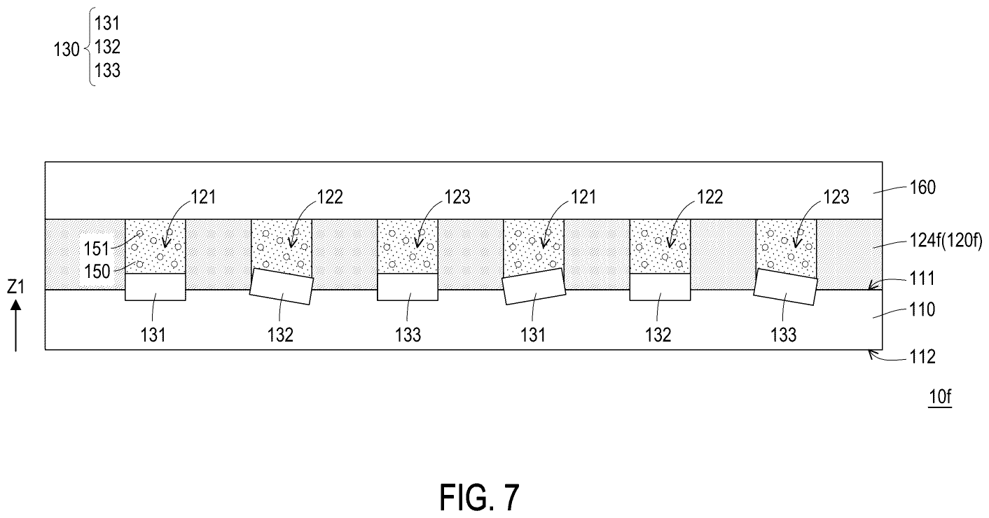

FIG. 7 is a cross-sectional schematic view of a display device according to the seventh embodiment of the disclosure. Please refer to FIG. 7 and FIG. 1 simultaneously. A display device 10f of the embodiment is similar to the display device 10 in FIG. 1. The difference between the two is that in the display device 10f of the embodiment, the partition 124f of the pixel definition layer 120f may include light-shielding material; thus, allowing the display device 10f of the embodiment to omit the black matrix layer as shown in FIG. 1.

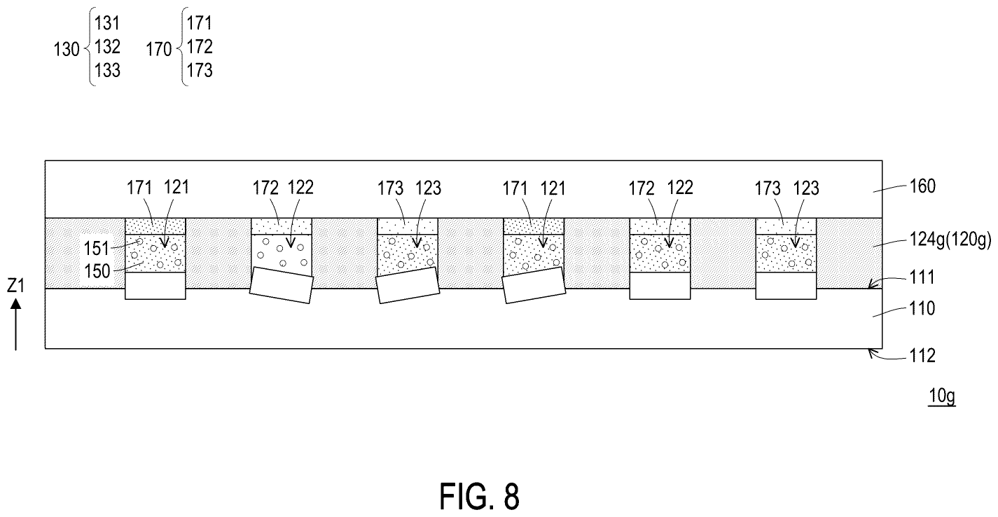

FIG. 8 is a cross-sectional schematic view of a display device according to the eighth embodiment of the disclosure. Please refer to FIG. 8 and FIG. 2 simultaneously. A display device 10g of the embodiment is similar to the display device 10a in FIG. 2. The difference between the two is that in the display device 10g of the embodiment, the partition 124g of the pixel definition layer 120g may include light-shielding material; thus, allowing the display device 10g of the embodiment to omit the black matrix layer as shown in FIG. 2.

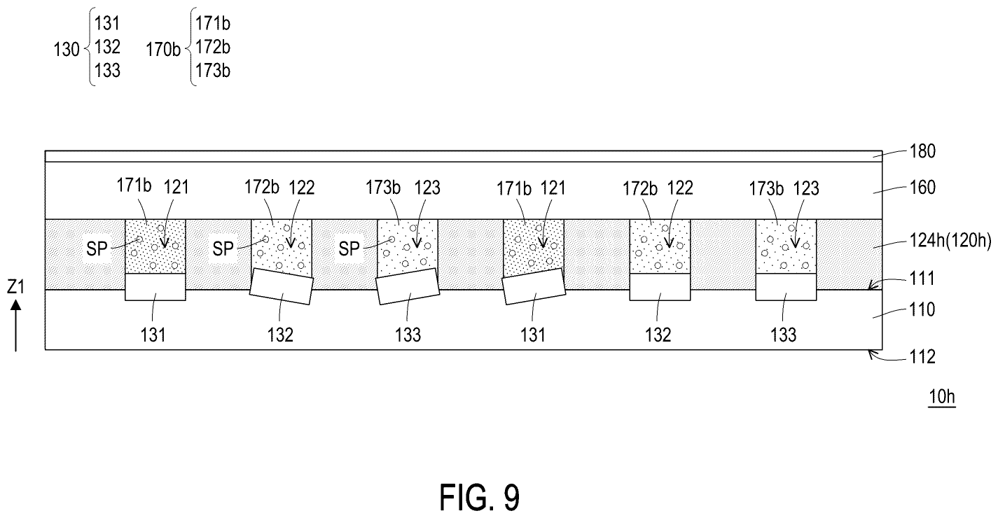

FIG. 9 is a cross-sectional schematic view of a display device according to the ninth embodiment of the disclosure. Please refer to FIG. 9 and FIG. 3 simultaneously. A display device 10h of the embodiment is similar to the display device 10b in FIG. 3. The difference between the two is that in the display device 10h of the embodiment, the partition 124h of the pixel definition layer 120h may include light-shielding material; thus, allowing the display device 10h of the embodiment to omit the black matrix layer as shown in FIG. 3.

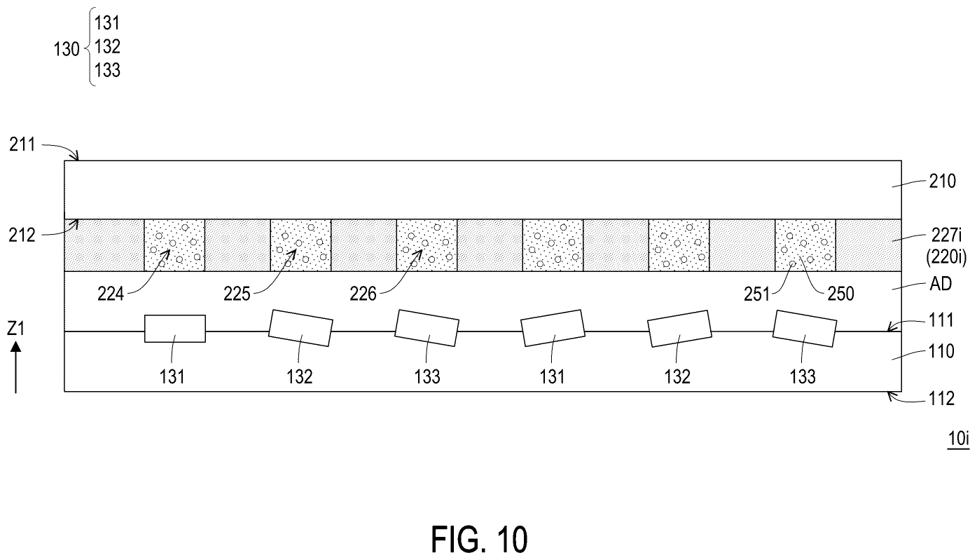

FIG. 10 is a cross-sectional schematic view of a display device according to the tenth embodiment of the disclosure. Please refer to FIG. 10 and FIG. 4 simultaneously. A display device 10i of the embodiment is similar to the display device 10c in FIG. 4. The difference between the two is that in the display device 10i of the embodiment, the partition 227i of the bank layer 220i may include light-shielding material; thus, allowing the display device 10i of the embodiment to omit the black matrix layer as shown in FIG. 4.

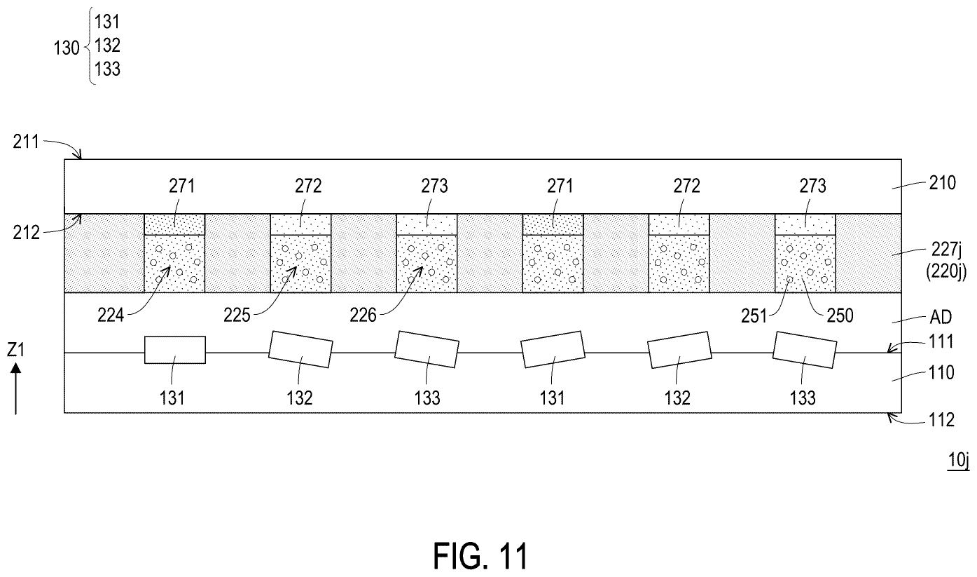

FIG. 11 is a cross-sectional schematic view of a display device according to the eleventh embodiment of the disclosure. Please refer to FIG. 11 and FIG. 5 simultaneously. A display device 10j of the embodiment is similar to the display device 10d in FIG. 5. The difference between the two is that in the display device 10j of the embodiment, the partition 227j of the bank layer 220j may include light-shielding material; thus, allowing the display device 10j of the embodiment to omit the black matrix layer as shown in FIG. 5.

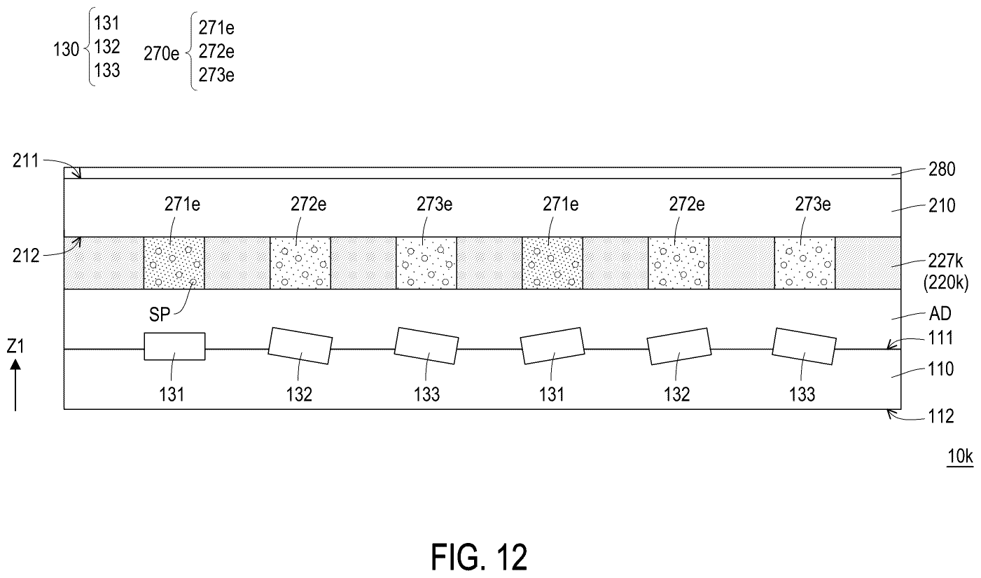

FIG. 12 is a cross-sectional schematic view of an electronic device according to the twelfth embodiment of the disclosure. Please refer to FIG. 12 and FIG. 6 simultaneously. A display device 10k of the embodiment is similar to the display device 10e in FIG. 6. The difference between the two is that in the display device 10k of the embodiment, the partition 227k of the bank layer 220k may include light-shielding material; thus, allowing the display device 10k of the embodiment to omit the black matrix layer as shown in FIG. 6.

In summary, in the display device of the embodiment of the disclosure, by disposing the scattering material layer on the light-emitting unit, by disposing the scattering material layer between the color filter unit and the light-emitting unit, or by disposing the color filter unit containing the scattering particle on the light-emitting unit, the scattering particle in the scattering material layer or the scattering particle in the color filter unit may be used to adjust the light-emitting direction (or light-emitting angle) of the tilted light-emitting unit, thereby improving the problem of uneven brightness when viewing from different viewing angles or maintaining similar brightness for the user when viewing from different angles.

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A display device, comprising:
a first substrate;
a plurality of light-emitting units, disposed on the first substrate, and comprising a first light-emitting unit, a second light-emitting unit, and a third light-emitting unit, wherein the first light-emitting unit, the second light-emitting unit, and the third light-emitting unit respectively emit light of different colors; and
a plurality of color filter units, disposed on the plurality of light-emitting units, and comprising a first color filter unit, a second color filter unit, and a third color filter unit, wherein the first color filter unit, the second color filter unit, and the third color filter unit respectively overlap the first light-emitting unit, the second light-emitting unit, and the third light-emitting unit;
wherein the first color filter unit, the second color filter unit, and the third color filter unit comprises a scattering particle.

2. The display device according to claim 1, further comprising:
a pixel definition layer, disposed on the first substrate, and comprising a first opening, a second opening, and a third opening,
wherein the first light-emitting unit and the first color filter unit are disposed in the first opening, the second light-emitting unit and the second color filter unit are disposed in the second opening, and the third light-emitting unit and the third color filter unit are disposed in the third opening.

3. The display device according to claim 2, further comprising:
a black matrix layer, disposed on the pixel definition layer, and comprising a plurality of fourth openings,
wherein the plurality of fourth openings respectively overlap the first light-emitting unit, the second light-emitting unit, and the third light-emitting unit.

4. The display device according to claim 3, wherein the plurality of fourth openings respectively overlap the first opening, the second opening, and the third opening.

5. The display device according to claim 3, further comprising:
a cover glass, disposed on the black matrix layer.

6. The display device according to claim 5, further comprising:
a functional layer, disposed on the cover glass, and comprising an anti-reflective layer and an anti-smudge layer.

7. The display device according to claim 2, wherein the pixel definition layer comprises a light-shielding material.

8. The display device according to claim 1, further comprising:
a second substrate, disposed opposite to the first substrate; and
an adhesive layer, disposed between the plurality of light-emitting units and the plurality of color filter units.

9. The display device according to claim 8, wherein there is a gap between the plurality of light-emitting units and the plurality of color filter units.

10. The display device according to claim 8, further comprising:
a bank layer, disposed on the second substrate, and comprising a fifth opening, a sixth opening, and a seventh opening,
wherein the first color filter unit is disposed in the fifth opening, the second color filter unit is disposed in the sixth opening, and the third color filter unit is disposed in the seventh opening.

11. The display device according to claim 10, further comprising:
a black matrix layer, disposed between the bank layer and the second substrate, and comprising a plurality of eighth openings,
wherein the plurality of eighth openings respectively overlap the first light-emitting unit, the second light-emitting unit, and the third light-emitting unit.

12. The display device according to claim 11, wherein the plurality of eighth openings respectively overlap the first opening, the second opening, and the third opening.

13. The display device according to claim 10, wherein the bank layer comprises a light-shielding material.

14. The display device according to claim 8, further comprising:
a functional layer, disposed on the second substrate, and comprising an anti-reflective layer and an anti-smudge layer.

15. The display device according to claim 1, wherein the scattering particle comprises titanium oxide, zinc oxide, silicon oxide, barium oxide, barium sulfate, or zirconium oxide.

16. The display device according to claim 1, wherein the first color filter unit, the second color filter unit, and the third color filter unit further comprise a heat-dissipating particle.

17. The display device according to claim 16, wherein a thermal conductivity coefficient of the heat-dissipating particle is between 50 W·m⁻¹·K⁻¹ and 1000 W·m⁻¹·K⁻¹.

18. The display device according to claim 1, wherein a normal direction of a portion of the plurality of light-emitting units is different from a normal direction of another portion of the plurality of light-emitting units.

19. The display device according to claim 1, wherein there is a tilt angle between a normal direction of a portion of the plurality of light-emitting units and a normal direction of the first substrate.

20. The display device according to claim 1, wherein the plurality of color filter units contact the plurality of light-emitting units.
